(19) United States
(12) Patent Application Publication
(10) Pub. No.: US 2019/0078800 A1
(43) Pub. Date: Mar. 14, 2019

(54) IMPROVED COOLING SYSTEM

(71) Applicant: FANDIS S.P.A., Milano (IT)

(72) Inventor: Roberto Brioschi, Borgo Ticino (IT)

(21) Appl. No.: 16/093,721

(22) PCT Filed: Apr. 20, 2016
(86) PCT No.: PCT/IT2016/000097

§ 371 Date: Oct. 15, 2018

(51) Int. Cl. F24F 11/30; F24F 11/77; G05D 23/24; H05K 7/20

(52) U.S. Cl. CPC F24F 11/30; F24F 11/77; F24F 2110/10; H05K 7/20181; G05D 23/24

(57) ABSTRACT

An improved cooling system is described, comprising: a containing case (3); a filter and fan assembly (1), inserted in a wall of the containing case (3); a filter (2) inserted in a wall of the containing case (3) and equipped with a protecting grid placed inside the case (3); a sensitive thermal-resistive element (11) applied onto the grid of every filter (2); and a control unit (10) connected to the sensitive element (11); wherein the sensitive element (11) has a thermal capability such that, with a power, and therefore a current, lower than 100 mW, a self-heating effect is obtained in unmoving air.

### BACKGROUND OF THE INVENTION

### 1) Field of the Invention

The present invention refers to an improved cooling system, in particular for electric cabinets. Such system is preferably composed of one or more filter assemblies (1), one or more filters (2) and a sensor composed of a sensitive thermal-resistive element (11) to be placed on the internal protecting grid of the filter (2) itself, and a control unit (10).

### 2) Background Art

With the current prior art, for heating electric cabinets, air filtering systems are used which are equipped with fans (axial fans, radial fans and the like) adapted to force air through filtering cloths aimed to filter air (see for example document EP-A-0864348).

In such known systems, the fan applied to the filter assembly must exceed the air resistance to cross the filter, resistance which appears with a load loss which increases the pressure difference between cabinet interior and exterior, with a consequent decrease of performances in terms of air flow-rate.

In particular, upon increasing the filtering element clogging, the further flow-rate decreases cannot be computed by a user and often can increase (even quickly in case of very dirty atmospheres) above the maximum value which covers a sufficient cooling of the device placed inside the electric cabinet.

A solution already adopted in this case is providing the cabinet interior with a thermostat which is triggered upon reaching a limit temperature, but such thermostat necessarily measures the temperature in a single spot, and a reduced internal ventilation (seen as air agitation inside the electric cabinet) is also associated with a reduced flow-rate, with a consequent creation of localized “hot spots”, which are dangerous and cannot be controlled.

Moreover, if the ventilation is wholly lacking, but the external temperature is low enough, this thermostat would not be triggered at all, while “hot spots” would remain present.

For an optimum control of temperature and of ventilation inside the cabinet, it would be ideal to be able to control several parameters and create better ventilation conditions.

The affected parameters are:
air flow-rate;
temperature inside the cabinet;
fan switching-on state.

The fans installed on filter assemblies can be of the sucking or pressing type (namely they can be able both to suck air inside the cabinet, and to pump spent air outside) and it is extremely interesting that, whichever type of sensor is adopted, it operates indifferently in the two senses.

Document WO 2006/097955 A1 (herein below, for conciseness, WO'955) of the same Applicant of the present invention solves the above prior art problems, but anyway does not provide for a system for measuring the air flow which keeps the measuring features.

### SUMMARY OF THE INVENTION

Therefore, object of the present invention is solving the previously mentioned prior art problems, by providing an improved cooling system capable of controlling the different alarm parameters, in order to guarantee an optimum control of temperature and ventilation inside a case. In particular, with respect to document WO'955, the present invention implements a system for measuring the air flow which keeps its measuring features: specifically, attention has been focuses on the measure of the air flow and on the measure of the temperature inside the electric panel.

The above and other objects and advantages of the invention, as will result from the following description, are obtained by an improved cooling system as claimed in claim 1. Preferred embodiments and non-trivial variations of the present invention are the subject matter of the dependent claims.

It is intended that the enclosed claims are an integral part of the present description.

### BRIEF DESCRIPTION OF THE DRAWINGS

The present invention will be better described by some preferred embodiments thereof, provided as a non-limiting example, with reference to the enclosed drawings, in which:

FIG. 1 shows a side sectional view of an embodiment of a prior art filter assembly;

FIG. 2 shows a side sectional view of an embodiment of a prior art filter;

FIG. 3 shows a graph representing the operating characteristic curve of a fan;

FIG. 4 shows the housing of the sensitive element on the internal grid of a filter in the system according to the present invention;

FIG. 5 shows a front sectional view of an electric cabinet in which the cooling system of the present invention is installed.

### DETAILED DESCRIPTION OF PREFERRED EMBODIMENTS

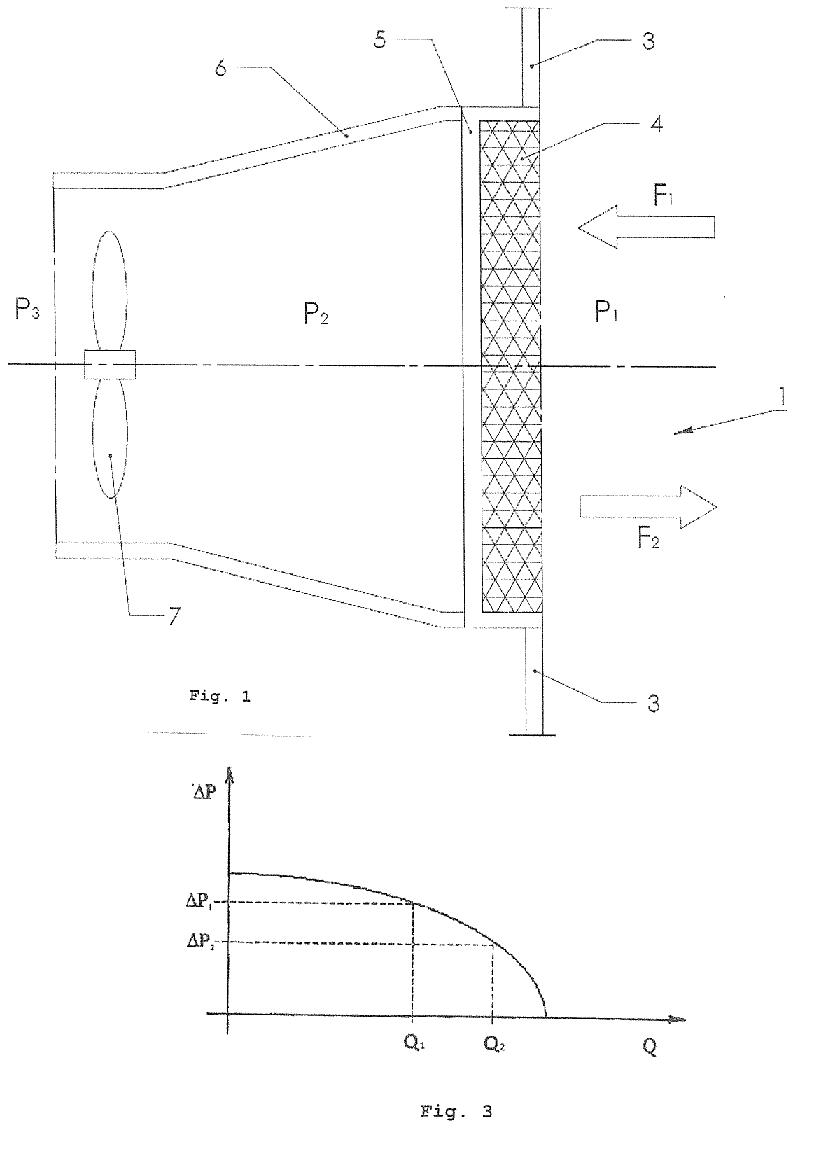

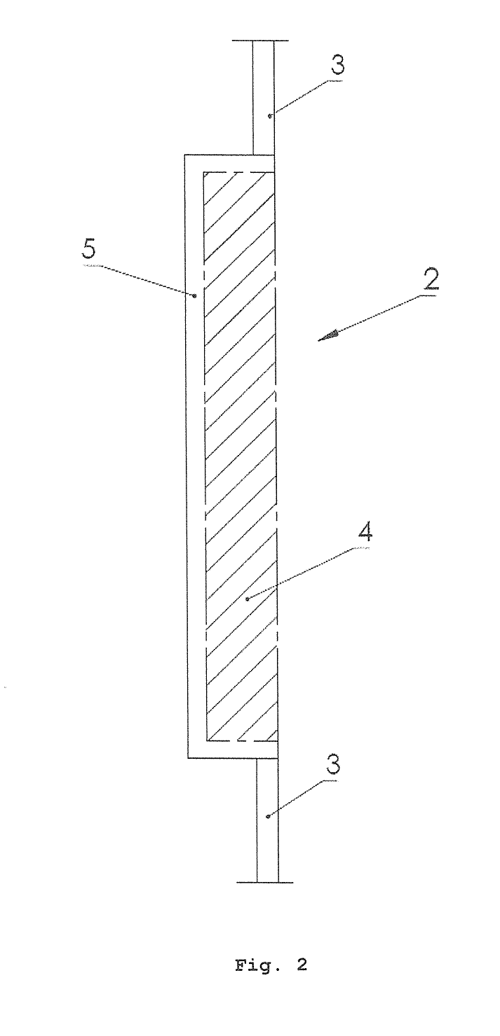

With reference to FIGS. 1 and 2, it is possible to note a filter assembly (1) for electric cabinets belonging to the prior art. Such filter assembly, inserted in a wall (3) of an electric case, is composed, as known, proceeding from outside towards inside the cabinet along the direction F1 of the air flow directed towards the electric panel to be cooled, of a filtering element (4), of a frame (5) for supporting a cloth, of a conveyor carter (6) and of a fan (7); in such configuration, substantially three pressure ranges are defined: P₁ is the external pressure, P₂ (equal to P₁ minus the load loss in the filter) is the intermediate pressure between the filtering element (4) and the fan (7) and P₃ (equal to P₂ plus the prevalence of the fan (7)) is the internal pressure. As already previously mentioned, it is clear that the fan (7) has to increase the air resistance to cross the filtering element (4), resistance which appears as a load loss which increases the pressure difference which the fan must exceed, with consequent decrease of performances in terms of air flow-rate.

Often, in case of clogging of the filtering element (4), air inside the case remains unmoving and layered.

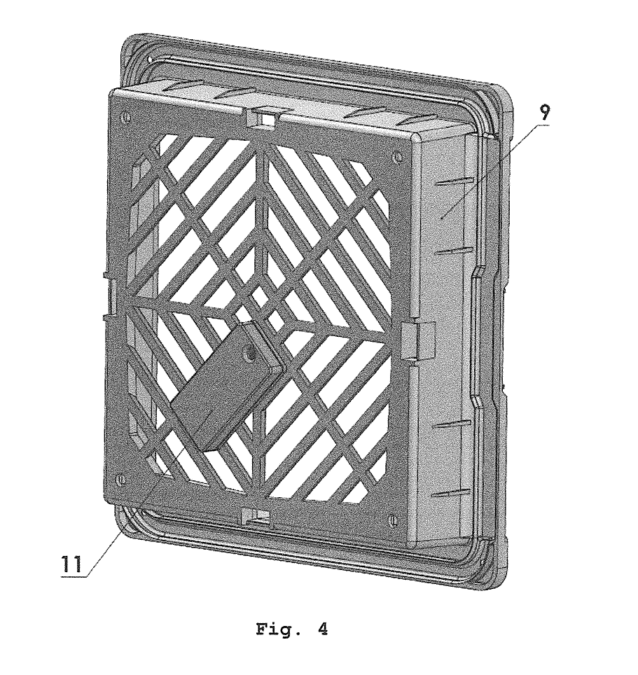

In FIG. 3, a graph is shown, as an example, of the flow-rate/pressure characteristic curve for the fan (7) (expressed in m³/h−Pa), using which, as an example, the flow-rate values Q₁ and Q₂ have been obtained as function of the respective measured pressure difference values ΔP₁ and ΔP₂.

The present invention aims to provide a measure of the air flow which transits through a case.

The technique used for measuring is the known one which employs a hot-wire anemometer. The operating principle is as follows: a thermal resistance or a heat-resistive sensor (11) changes its internal resistance when the temperature to which it is subjected changes. It is possible then to obtain its temperature by measuring this resistive value with an external ohm-meter.

In order to be able to perform the measure, however, it is necessary that a current travels in the sensor, and to measure the resistance which the sensor opposes to being crossed: the act of making the current travel therein automatically heats the sensor according to the famous Joule Law (W=RI²) introducing a systematic error.

The improved cooling system according to the present invention advantageously exploits this systematic error, increasing it and obtaining from its variability, all information of interest, as will be seen below in the present description.

In practice, it is important that the sensitive thermal-resistive element (11) used in the present invention has a small thermal capability, so that, with small powers (and then currents) lower than 100 mW, a strong self-heating effect is obtained (ex. 1° C./50 mW) in unmoving air. The solution according to the present invention is therefore providing a system with low thermal inertia to guarantee quick frequency responses.

According to the improved cooling system of the invention, by supplying a small resistance or a thermistor (11) with small currents, and by exploiting the ohmic resistance variation upon changing the temperature, it is possible to estimate the amount of air necessary for removing the developed thermal power, in order to afterwards acquire the data through a microcontroller device.

The system (due to the principle of overlapping of effects) is wholly independent from the absolute value of the temperature in the case.

It is advantageous that the sensitive thermal-resistive element (11) of the improved cooling system according to the present invention also operates as measuring device of the internal temperature.

The improved cooling system embeds a sensitive element (11) exposed to the air flow, and a control unit (10) inside the case (3) for managing the signal received from the sensitive element (11) through the use of a microcontroller, and also integrates the thermostatic function.

The measure of the air flow is then used by the control unit (10) for signals which are both visual and remotely transmitted.

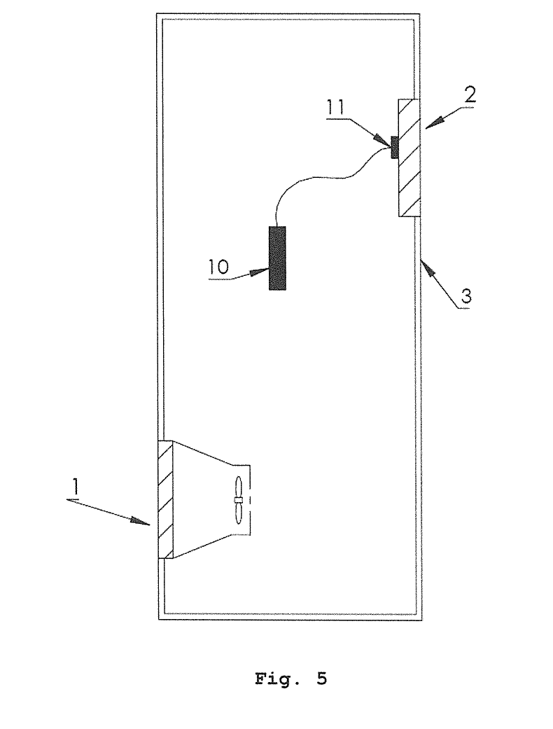

With reference in particular to FIG. 5, it is possible to note a preferred embodiment of the improved cooling system according to the present invention; such system comprises at least one filter and fan assembly (1), inserted in the wall of a containing case (3), at least one filter (2), at least one sensitive thermal-resistive element (11) applied onto the internal grid of every filter (2) and a control unit (10) connected to the sensitive thermal-resistive element (11).

As shown in FIG. 4, the sensitive thermal-resistive element (11) is applied onto the internal grid of the filter (2) by means of a fastening element which can be suited to the different types of filter (2) size.

In this way, a retrofitting of the system is guaranteed with filters of previous series.

This configuration enables to use the sensitive element (11) for measuring both the real air flow which goes out of the case, and the temperature inside the case itself, providing the chance of obtaining the following results:
a thermostat capable of generating the alarms and/or of controlling the speed of the fan of the filter and fan assembly (1), thereby replacing a further component inside the case (3);
the measure of the air flow-rate, on which an alarm signal can be placed, which can be remotely sent outside and which, in a limit case, physically intervenes on users (not shown) inside the case (3).

The improved cooling system according to the present invention operates independently from any cause which generates the flow-rate reduction, since the real air flow-rate going out of the case is measured.

The improved cooling system according to the present invention has been so far described as used for venting electric cabinets, since this is its most typical industrial application, but it is clear that it can be used in any other field in which the same inventive features are required, such as for example in checking the operation of suction hoods, without departing from the scope of the present invention.

1-8. (canceled)

9. A cooling system comprising:
a containing case;
at least one filter and fan assembly, preferably inserted in a wall of the containing case;
at least one filter inserted in a wall of the containing case and equipped with a protecting grid placed inside the containing case;
at least one sensitive thermal-resistive element applied onto the grid of every filter; and
a control unit connected to the sensitive thermal-resistive element;
wherein the sensitive thermal-resistive element is designed for measuring both a real air flow which goes out of the case and a temperature inside the case, the sensitive thermal-resistive element having a thermal capability such that, with a power, and therefore a current, lower than 100 mW, a self-heating effect is obtained in unmoving air.

10. The cooling system of claim 9, wherein, by supplying the sensitive thermal-resistive element with the current, and by exploiting a variation of an ohmic resistance when the temperature changes, it is possible to estimate the amount of air necessary for removing the developed thermal power, in order to afterwards acquire the data through the control unit.

11. The cooling system of claim 9, wherein the cooling system also operates as meter of an internal temperature of the case.

12. The cooling system of claim 9, wherein the sensitive thermal-resistive element is exposed to an air flow which penetrates inside the case and the control unit placed inside the case is adapted to manage the signal received from the sensitive element through the use of a microcontroller, and also to integrate a thermostatic function.

13. The cooling system of claim 12, wherein a measure of the air flow is then used by the control unit for a visual or remotely-transmitted signal.

14. The cooling system of claim 9, wherein the sensitive thermal-resistive element is applied onto the internal grid of the filter by means of a fastening element which is suited to different types of filter size.

15. The cooling system of claim 9, wherein the cooling system operates as thermostat capable of generating the alarms and/or of checking the speed of the fan of the filter and fan assembly, thereby replacing a further component inside the case.

16. The cooling system of claim 9, wherein the cooling system operates for performing the measure of the air flow-rate, on which an alarm signal can be placed, which can be remotely transmitted outside and which, in a limit case, physically intervenes on users inside the case.
